(19) United States
(12) Patent Application Publication
(10) Pub. No.: US 2014/0151311 A1
(43) Pub. Date: Jun. 5, 2014

(54) Mount For Electrical Equipment

(71) Applicant: Control Techniques Limited, Newtown (GB)

(72) Inventor: Charles Anthony Cachia, Welshpool (GB)

(73) Assignee: Control Techniques Limited, Newtown (GB)

(21) Appl. No.: 14/093,683

(22) Filed: Dec. 2, 2013

(30) Foreign Application Priority Data
Nov. 30, 2012 (GB) 1221593.5

(51) Int. Cl. H05K 7/14

(52) U.S. Cl. CPC H05K 7/14
USPC 211/26.2

(57) ABSTRACT

A mount for supporting a housing of electrical equipment comprises a rectangular frame and a floating strut which rests on the frame to sub-divide the aperture into smaller spaces each for a housing. The frame of the strut engages a gasket on the housing to seal each side of the frame from the other. Multiple housings can be installed in the same frame and the strut and gaskets provide sealing between in the inside and the outside of the frame.

### CROSS-REFERENCE TO RELATED APPLICATION

This application claims the benefit and priority of Great Britain Patent Application No. 1221593.5, filed Nov. 30, 2012. The entire disclosure of the above application is incorporated herein by reference.

### DESCRIPTION

This invention relates to a mount for electrical equipment, such as a drive controller for an electric motor.

The installation of electrical equipment in a site requires the individual unit to be mounted in a logical and/or orderly manner usually within a bulkhead. The term “electrical equipment” includes any processor-based or data processing equipment. For example, a drive for controlling an electric motor typically comes in its own housing which is mounted in a bulkhead of an enclosure. Each housing can be mounted individually in the bulkhead. One of the problems that all such installations face is the airborne dust, water and debris that can contaminate the equipment. This can be exacerbated by the common need of electrical equipment for cooling fans to circulate air through the housing to prevent components overheating. Cooling fans draw in airborne particulates and direct them into the housing. To address this it is known to install such equipment with part of the housing projecting from the bulkhead into a clean air (filtered) environment.

A bulkhead may have to accommodate multiple housings (of multiple electrical equipment). Each can have its own aperture in the bulkhead. For reasons of economy of space it is better to group the housings together in a single opening. However, this presents a problem in that there are gaps between the housings that can allow “dirty” air into the space inside the enclosure (behind the bulkhead). The housings can be made with flat adjacent surfaces that mate so as not to leave a gap. In practice this is rarely adequate due to manufacturing and installation tolerances.

What is needed is a reliably sealable bulkhead fitting for mounting a housing of electrical equipment.

According to disclosed embodiments there is provided a bulkhead fitting for mounting multiple housings (or cabinets or chassis) of electrical equipment, comprising a bulkhead defining a generally rectangular aperture for multiple housings which are adapted to mate with edges of the bulkhead defining part of the aperture, a strut engaged with opposite sides of the bulkhead able to adopt a position along the edges between adjacent housings, providing a further mating edge for the adjacent housings.

In one form there is provided a mount for multiple housings of electrical equipment, comprising a frame defining an aperture, one or more struts (or support bars or beams) resting between opposed sides of the frame defining the aperture, the aperture being sub-divided by the struts to define corresponding multiple through holes for mounting the housings.

Preferably, the strut supports a gasket that can seal against the ingress of dirt and particulates across the bulkhead. Preferably, the gasket is also supported by the frame. Preferably, the strut has a stiffening portion in between the opposed sides of the frame which improves the rigidity of or strengthens the strut.

The frame may be part of the bulkhead or it may be a separate item which is itself mounted in the bulkhead.

An assembly of multiple housings each of electrical equipment can be installed in the respective sub-divisions of the aperture. Each housing can define a sealing surface that engages the sides of the frame and the supporting bar in the aperture.

Embodiments will now be described by way of example with reference to the accompanying drawings in which:

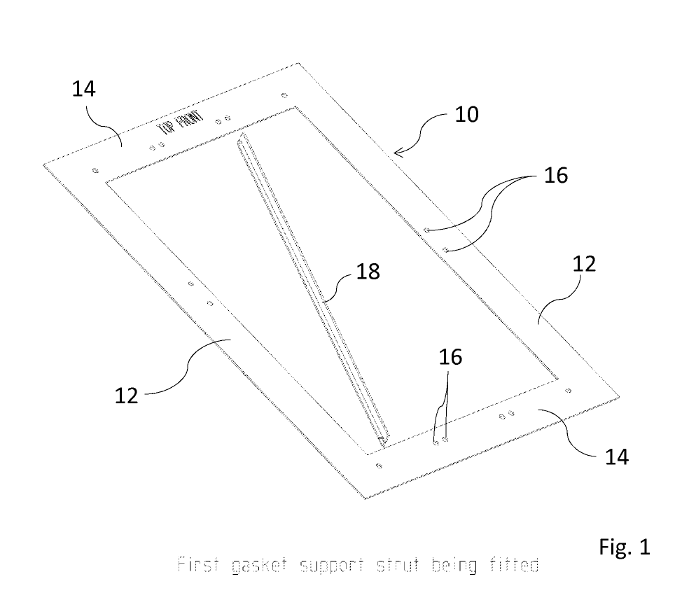

FIG. 1 is a front view of a mounting frame for a bulkhead;

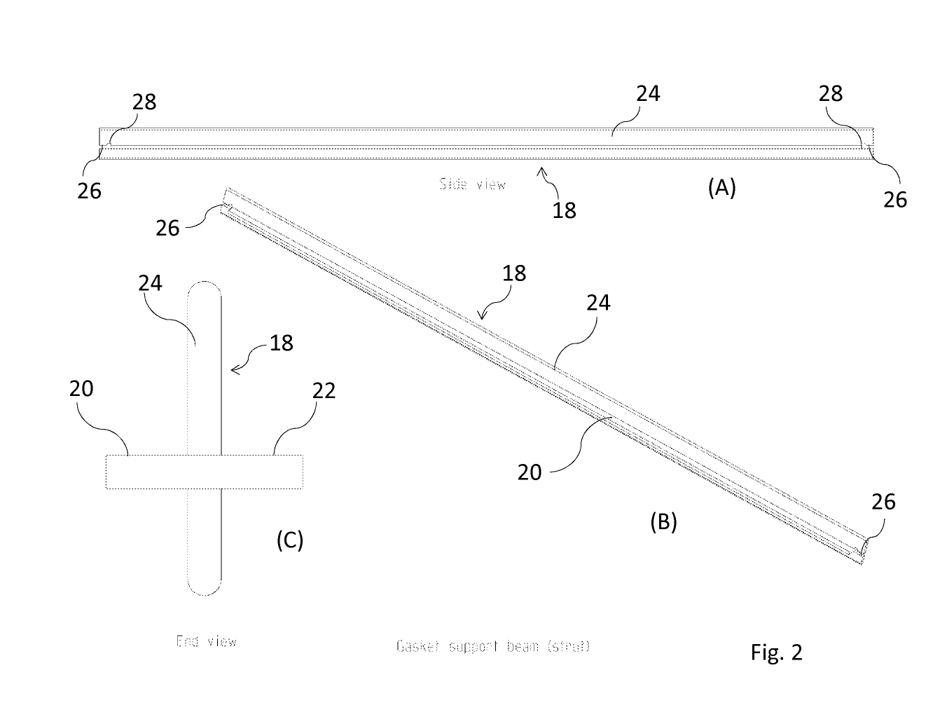

FIGS. 2A, B, C are views of a strut shown in FIG. 1; and

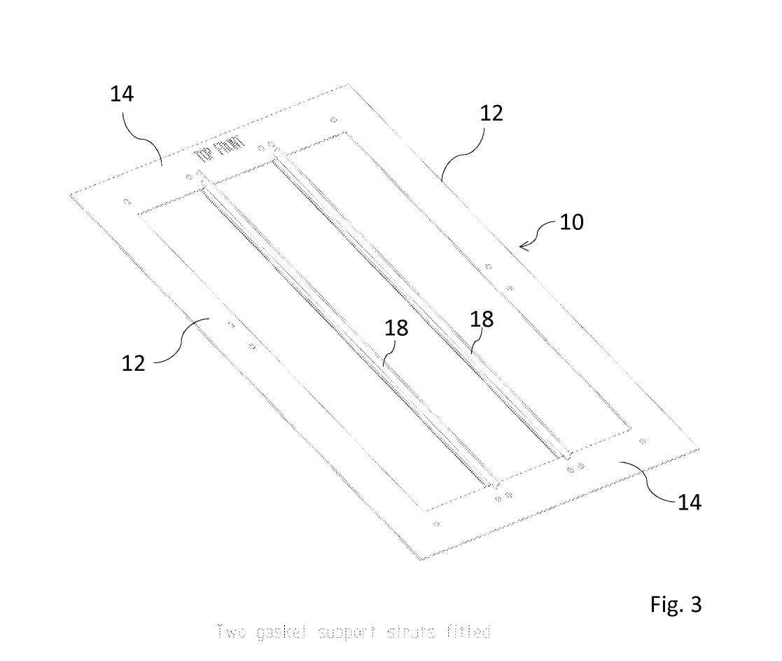

FIGS. 3-7 are views of various stages of assembly of a mounting frame for housings of electrical equipment.

Referring to FIGS. 1 and 2, a mounting frame 10 for a housing of electrical equipment is a rectangle of steel or aluminium plate of opposed long and short sides 12/14. It could, of course, be a rigid plastics material or any other suitable metal sufficiently strong to hold a housing of electrical equipment. The frame is itself located in an aperture of a bulkhead (not shown). The frame 10 has spaced holes 16 for fastening devices as described below. Also shown in the drawings is a separate gasket strut 18 which is shown in more detail in FIG. 2. The strut 18 comprises longitudinally running support flanges 20 and 22 which extend from a central stiffening rib 24. The flanges 20 and 22 are a clearance fit between opposing edges of the two short sides 14 of the frame. The rib 24 extends beyond the flanges longitudinally across part of the adjacent surfaces of the short sides to define a jaw 26 at each end of the strut 18 that engages about its corresponding edge of the respective short sides 14 of the frame. The inner part of each jaw 26 is radiused and has a diameter that is greater than the jaw spacing. The radius also helps to reduce stresses in the surrounding area. The recess 28 thus formed provides a clearance that allows the strut 18 to rest on the sides without snagging any inconsistencies in the otherwise straight edge of the short arms caused by, for example, damage or manufacturing defects. The strut 18 is introduced on to the frame 10 diagonally and rotated so that each end engages its corresponding short side 14. The strut 18 is then free to slide along the sides.

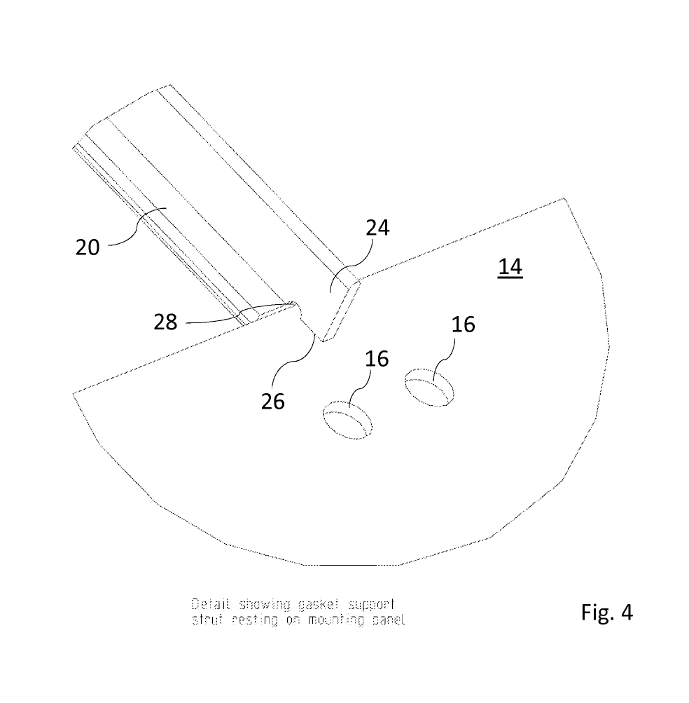

In place the strut 18 rests on a front (outer) face of the frame 10. FIG. 3 shows a pair of such struts 12 in position on the frame 10. Detail of one end of the strut 18 on its corresponding short side 14 is shown in FIG. 4. The upper surface of each flange 20/22 is flush with the adjacent surface of the short side 14. The clearance provided by the radius in the end of the jaw 26 can be seen.

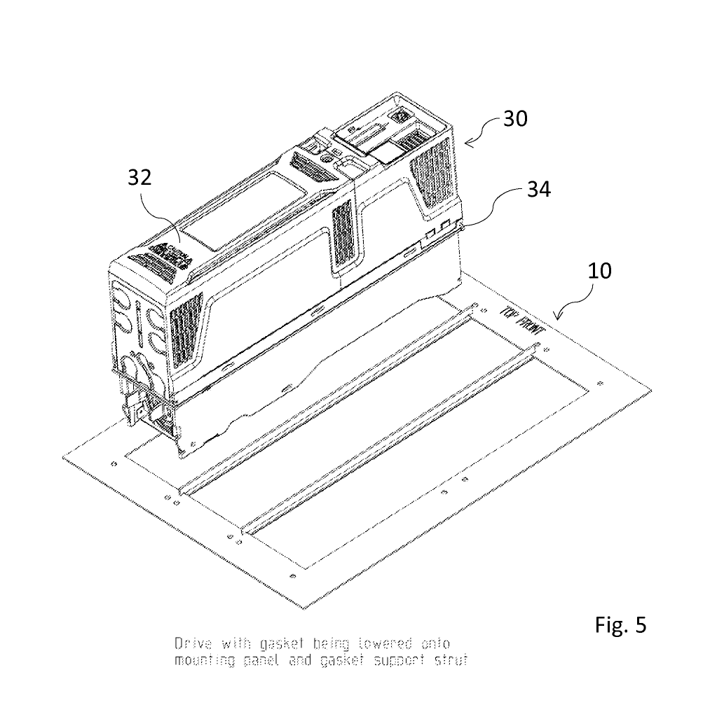

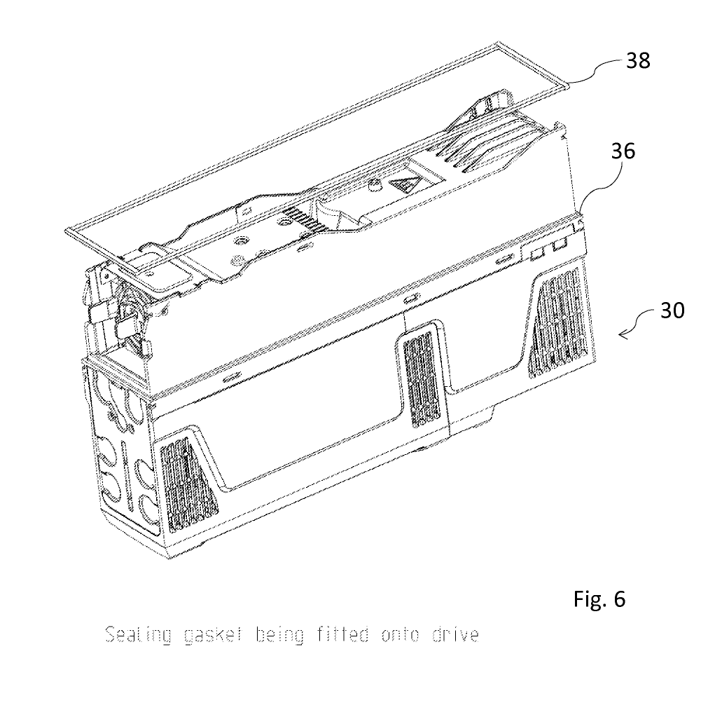

In FIG. 5 a housing 30 which houses, in this case, a processor-based, electrical, motor controller is shown being arranged for insertion in the frame 10 between one of the long sides 12 of the frame and one of the struts 18. The housing 30 houses processing and control circuitry and cooling fans, and is in its function conventional. The outer face 32 of the housing 30 provides interfaces for inserting memory devices, plugging in other equipment such as diagnostic equipment and the like. At the junction 34 between the front part of housing 12 and the back there is a rearward facing flat ledge 36 which extends around the housing. A gasket 38 of elastomeric material is arranged on this ledge 36 and is shown in FIG. 6. It mates with the front facing surfaces of the long side 12, the adjacent surfaces of the short sides 14 and the flush surface of one of the flanges 20 of the strut 18. The assembly thus provides a simple but very effective seal between the opposite sides of the frame. The strut 18 is located in position adjacent housing 30 but is also held securely in place by the jaws engaging the sides of the frame at opposite ends such that the pressure exerted by the housing 30 on the flange of the strut 18 is sufficient to hold it in place. The rigidity of the strut 18 is enhanced by the rib 24 and provides a supporting surface for the gasket 38 to seal against the ledge of the housing.

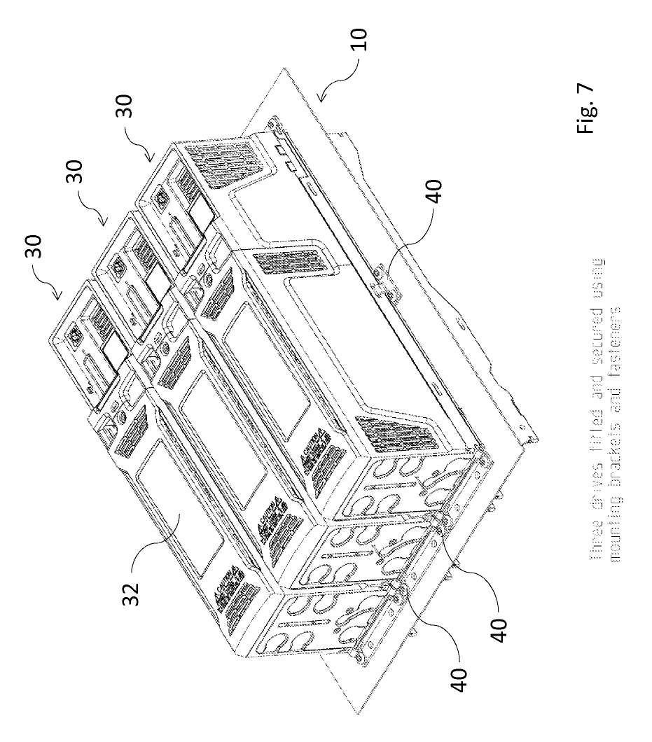

The front and rear of the frame are sealed from one another by multiple housings being installed in the spaces between the struts 18 and the long sides 12 of the frame 10 as shown in FIG. 7. The other outer housing engages the opposite long side of the frame from that shown. The middle housing engages two of the struts 18 instead. The housings are retained in position in the frame 10 by clamps 40 that are fastened in the holes 16 referred to above that are formed in the frame. The frame itself is then loaded into a suitably dimensioned aperture in a bulkhead between a control space into which the front of the housings face and a clean environment into which the rears of the housings extend. In some embodiments, the aperture is cut directly into the bulkhead, or rear panel of the enclosure.

The frame assembly provides a very efficient way of sealing multiple housings in the same frame or bulkhead and provides a fully sealed junction between the two sides of the frames or bulkhead. The housings can be of different widths. The struts 18 are easily moved along the sides of the frame to fit the housing dimensions.

In some embodiments, there are fans on both sides of the enclosure. The outside is considered as the ‘dirty’ air environment, while the inside is considered as the clean air (filtered) environment. The fans on the outside thus circulate or blow dirty air on the outside of the bulkhead and the fans on the inside circulate clean or filtered air on the inside of the bulkhead. In other embodiments, the fans are only on the inside. Natural convection currents are relied upon for cooling the part of the equipment on the outside. In all of these embodiments, the sealing gasket stops ‘dirty’ air contaminated with dust and water found on the outside from entering inside where the clean air is circulating.

1. A mount for multiple housings of electrical equipment, comprising a frame defining an aperture, and one or more struts resting on and positionable between opposed sides of the frame defining the aperture, the aperture being sub-divided by the struts to define corresponding multiple through holes for mounting the housings, wherein the or each strut has a surface that is flush with the surface defining the aperture and is slidable along the opposed sides of the frame.

2. A mount as claimed in claim 1 in which the strut supports a gasket.

3. A mount as claimed in claim 2 in which the gasket is also supported by the frame.

4. A mount as claimed in claim 1 in which the strut has a stiffening portion in between the opposed sides of the frame.

5. A mount as claimed in claim 1 in which the frame is part of a bulkhead.

6. A mount as claimed in claim 1 in which the frame is separate from but retained by a bulkhead.

7. An assembly of a mount as claimed in claim 1 and multiple housings of electrical equipment installed in the respective sub-divisions of the aperture.

8. An assembly as claimed in claim 7 in which each housing defines a sealing surface that engages the edges of the frame and the supporting strut in the aperture.
